(19) United States
(12) Patent Application Publication
(10) Pub. No.: US 2026/0299000 A1
(43) Pub. Date: Oct. 1, 2026

(54) DETECTING POWER GRID SHORTS ON REGULATED VOLTAGE DOMAINS

(71) Applicant: INTERNATIONAL BUSINESS MACHINES CORPORATION, ARMONK, NY (US)

(72) Inventors: MICHAEL SPERLING, POUGHKEEPSIE, NY (US); JENS DACI, POUGHKEEPSIE, NY (US); HUNTER FENG SHI, GLENDALE, NY (US)

(21) Appl. No.: 19/095,350

(22) Filed: Mar. 31, 2025

(51) Int. Cl. G01R 31/08; G01R 19/10; G01R 19/165; G01R 31/52

(52) U.S. Cl. CPC G01R 31/088; G01R 19/10; G01R 19/16538; G01R 31/52

(57) ABSTRACT

Detecting power grid shorts on regulated voltage domains including providing an integrated circuit having a first voltage regulator in a voltage domain, a first circuit under test, a regulator disable logic unit, and a short detection logic unit; applying a voltage to the first circuit under test via the first voltage regulator; disabling the first voltage regulator by the regulator disable logic unit; after disabling the first voltage regulator, comparing, by the short detection logic unit, an output voltage of the first voltage regulator to a circuit leakage voltage value expected for the first circuit under test; and determining that a short exists by detecting that a difference between the output voltage of the first voltage regulator and the circuit leakage voltage value is greater than a threshold.

### BACKGROUND

The present disclosure relates to methods, apparatus, and products for detecting power grid shorts on regulated voltage domains.

### SUMMARY

According to embodiments of the present disclosure, various methods, apparatus and products for detecting power grid shorts on regulated voltage domains are described herein. In some aspects, detecting power grid shorts on regulated voltage domains includes providing an integrated circuit having a first voltage regulator in a voltage domain, a first circuit under test, a regulator disable logic unit, and a short detection logic unit; applying a voltage to the first circuit under test via the first voltage regulator; disabling the first voltage regulator by the regulator disable logic unit; after disabling the first voltage regulator, comparing, by the short detection logic unit, an output voltage of the first voltage regulator to a circuit leakage voltage value expected for the first circuit under test; and determining that a short exists by detecting that a difference between the output voltage of the first voltage regulator and the circuit leakage voltage value is greater than a threshold.

### BRIEF DESCRIPTION OF THE DRAWINGS

FIG. 1 sets forth an example computing environment according to aspects of the present disclosure.

FIG. 2 sets forth an example system for detecting power grid shorts on regulated voltage domains according to aspects of the present disclosure.

FIG. 3 sets forth a flowchart of an example method for detecting power grid shorts on regulated voltage domains according to aspects of the present disclosure.

### DETAILED DESCRIPTION

Power grids within integrated circuits may develop shorts between power and ground that are difficult to detect. Aspects of the present disclosure may be used to detect whether a short exists within a voltage domain. This is accomplished by measuring the circuit leakage after a regulator for the voltage domain has been switched off and comparing the output voltage to the expected circuit leakage for the circuit.

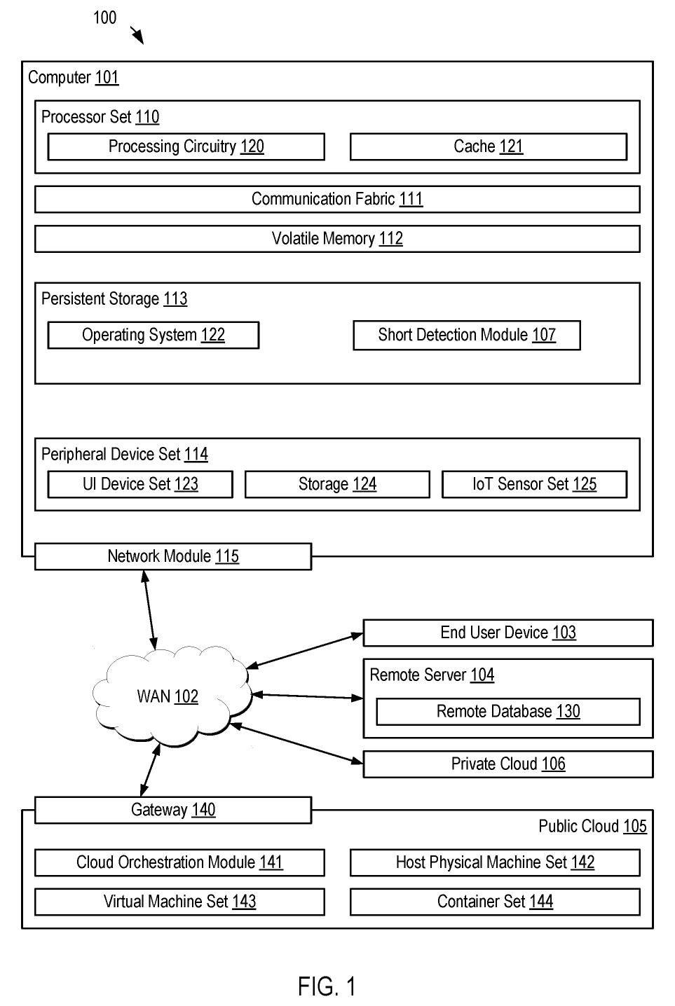

FIG. 1 sets forth an example computing environment according to aspects of the present disclosure. Computing environment 100 contains an example of an environment for the execution of at least some of the computer code involved in performing the various methods described herein, such as short detection module 107. In addition to short detection module 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and short detection module 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in short detection module 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in short detection module 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

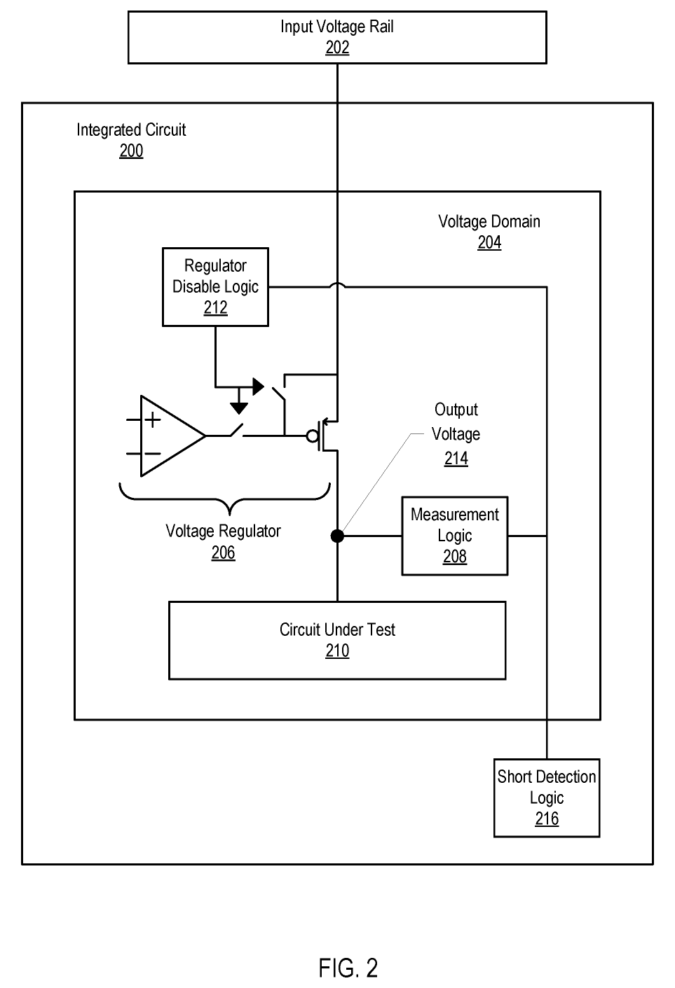

FIG. 2 sets forth an example system for detecting power grid shorts on regulated voltage domains according to aspects of the present disclosure. As shown in in FIG. 2, the example system includes an input voltage rail 202 that supplies power to an integrated circuit 200. The integrated circuit 200 includes a voltage domain 204. The voltage domain 204 includes a voltage regulator 206, a regulator disable logic unit 212, a measurement logic unit 208, and a circuit 210. The measurement logic unit 208 measures the voltage at an output voltage 214 point at the output of the voltage regulator 206. The short detection logic unit 216 uses the regulator disable logic unit 212 and the measurement logic unit 208 to detect shorts within the integrated circuit.

The input voltage rail 202 is a medium through which voltage is supplied to the integrated circuit 200 and one or more voltage domains 204. The integrated circuit 200 is a collection of electronic components and interconnections etched into a semiconductor material. The integrated circuit 200 may include, for example, a processing unit, data storage, power management, or input and output functions. The integrated circuit 200 may include one or more voltage domains. A voltage domain 204 is a group of electronic components that share a voltage supply.

The voltage regulator 206 is a circuit that is designed to maintain a constant output voltage level as operating conditions change over time. That is, the voltage regulator receives an input voltage and automatically maintains a constant voltage level on one or more output terminals. There are several types of voltage regulators such as, for example, switching regulators, linear regulators, and cascaded regulators that may include both switching and linear regulators in a cascaded architecture. One particular type of linear regulator that may be used is a low-dropout (LDO) regulator. An LDO regulator is a linear voltage regulator that may regulate the output voltage even when the supply voltage is close to the output voltage. That is, the LDO regulator may maintain voltage regulation with small differences between supply voltage and load voltage. Another type of voltage regulator is a buck switching regulator (e.g., a step-down regulator circuit). The buck switching regulator is a type of switch mode power supply circuit designed to efficiently reduce voltage from a higher voltage to a lower voltage.

As shown in FIG. 2, the voltage regulator 206 includes an amplifier and a transistor. The amplifier acts as a control for the voltage across the gate of the transistor. The voltage regulator 206 also includes circuitry for enabling and disabling the voltage regulator 206, which is controlled by the regulator disable logic unit 212. Specifically, the regulator disable logic unit 212 uses the switches within the circuitry to disable the transistor by opening the switch on the voltage regulator and closing the switch from the input voltage rail 202. Multiple voltage regulators may be distributed across the voltage domain 204 to regulate the voltage across different loads.

The measurement logic unit 208 is a collection of electronic components configured to measure the output voltage 214 of the voltage regulator 206 at the point of connection to the circuit under test 210. The measurement logic unit 208 may also be configured to compare the output voltage 214 of the voltage regulator 206 to a circuit leakage voltage for the circuit under test 210. The results of the comparison may be sent to the short detection module. Alternatively, the measurement logic unit 208 may also determine whether the difference between the output voltage 214 of the voltage regulator 206 and the circuit leakage voltage is greater than a threshold and send the determination to the short detection module.

The measurement logic unit 208 may be within the voltage domain 204 on the integrated circuit 200. Alternatively, a portion or all of the measurement logic unit 208 may exist outside of the voltage domain 204 but within the integrated circuit 200 or outside the integrated circuit 200. Further, the measurement logic unit 208 may receive operational instructions from a short detection module on a computer system, such as the short detection module on the computer system of FIG. 1.

The short detection logic unit 216 is a collection of electronic components configured to enable and disable the voltage regulator 206 via the regulator disable logic unit 212 and to measure the output voltage 214 using the measurement logic unit 208. The short detection logic unit 216 uses the process below to detect shorts within the integrated circuit 200 and may communicate the results with the short detection module of FIG. 1. The short detection logic unit 216 may be external to the voltage domain 204 as shown in FIG. 2 or may be within voltage domain 204.

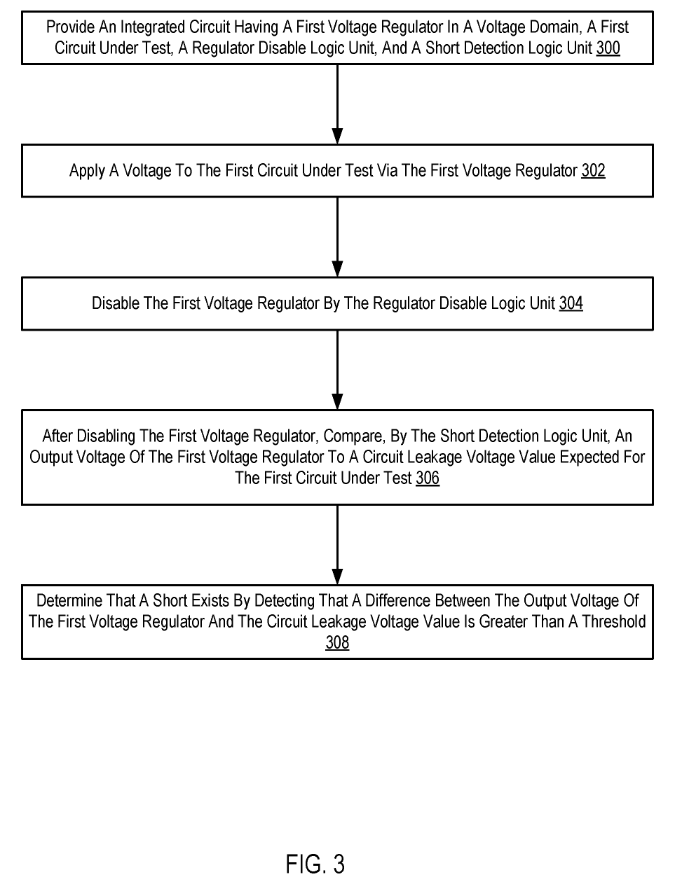

FIG. 3 sets forth a flowchart of an example method for detecting power grid shorts on regulated voltage domains according to aspects of the present disclosure. The method of FIG. 3 describes testing a particular circuit by measuring the input voltage of the circuit after the voltage to the circuit has been turned off. If the measured input voltage to the circuit is higher than the expected leakage voltage, then a short likely exists with the particular circuit. The method of FIG. 3 may be performed before and/or after other circuits are tested and no short is detected.

The method of FIG. 3 includes providing 300 an integrated circuit having a first voltage regulator in a voltage domain, a first circuit under test, a regulator disable logic unit, and a short detection logic unit. An integrated circuit, such as that described in FIG. 2, may be provided.

The method of FIG. 3 also includes applying 302 a voltage to the first circuit under test via the first voltage regulator. In one or more embodiments, applying 302 a voltage to the first circuit under test via the first voltage regulator is carried out by introducing a voltage to one or more pins of the integrated circuit. The voltage applied may be a voltage for which the integrated circuit has been designed. An input voltage rail may provide power to a first circuit under test via the first voltage regulator. Applying 302 a voltage to the first voltage regulator may also include enabling the first voltage regulator such that voltage is supplied to the first circuit under test. The first voltage regulator maintains a constant voltage to the first circuit under test and may be one of multiple voltage regulators within the voltage domain. The voltage may be applied to the input voltage rail for a at least an amount of time sufficient to fully power the circuit under test.

The method of FIG. 3 also includes disabling 304 the first voltage regulator by the regulator disable logic unit. In one or more embodiments, disabling 304 the first voltage regulator by the regulator disable logic unit is carried out by adjusting the first voltage regulator such that no voltage is supplied at the drain of the transistor. Specifically, the PFET of the first voltage regulator may be turned off using the switches and the regulator disable logic unit. Disabling 304 the first voltage regulator may also be carried out by disabling each voltage regulator in the voltage domain that could provide voltage to the first circuit under test.

The method of FIG. 3 also includes after disabling the first voltage regulator, comparing 306, by the short detection logic unit, an output voltage of the first voltage regulator to a circuit leakage voltage value expected for the first circuit under test. In one or more embodiments, comparing 306 , by the short detection logic unit, an output voltage of the first voltage regulator to a circuit leakage voltage value expected for the first circuit under test is carried out by measuring the output voltage at a connection to the drain of first voltage regulator (e.g., by the measuring logic unit). The output voltage refers to the voltage provided by the first voltage regulator (either enabled or disabled). The circuit leakage voltage value is the voltage value measured on the circuit while the circuit is considered to be off. Specifically, the circuit leakage voltage value refers to the voltage level on a circuit without supplying that circuit with an intentional voltage. The circuit leakage voltage value is lower than the voltage provided while the circuit is operational. The circuit leakage voltage value may be determined using other integrated circuits manufactured using the same design. The circuit leakage voltage value is predetermined.

The method of FIG. 3 also includes determining 308 that a short exists by detecting that a difference between the output voltage of the first voltage regulator and the circuit leakage voltage value is greater than a threshold. In one or more embodiments, determining 308 that a short exists by detecting that a difference between the output voltage of the first voltage regulator and the circuit leakage voltage value is greater than a threshold is carried out by measuring the difference between the output voltage and the circuit leakage voltage value from the comparison and determining whether that difference is greater than the threshold. Specifically, the threshold is an acceptable range of leakage voltage of the first voltage regulator above the circuit leakage voltage value. The threshold is an amount of acceptable voltage tolerance between the output voltage of the voltage regulator and the (expected) leakage voltage. The threshold may be based on measurements from other integrated circuits tested previously.

Detecting that a difference between the output voltage and the circuit leakage voltage value is greater than the threshold indicates that a short exists. A short is the occurrence of a voltage traveling across an unintended path. Shorts in an integrated circuit may develop over time or because of a manufacturing defect. Further, a short may develop within the circuit under test, within the voltage domain, or within one or more voltage regulators.

Once the measurement logic unit and/or the short detection module determines that the difference between the output voltage and the circuit leakage voltage is greater than the threshold, then integrated circuit may be marked as defective. Alternatively, the measurement logic unit or other mechanism may be used to disable the circuit under test permanently.

Once the first circuit under test is tested for shorts, additional tests may be performed on other circuits. For example, the method may further include applying the voltage to the input voltage rail that provides power to a second circuit under test via a second voltage regulator; disabling the second voltage regulator; after disabling the second voltage regulator, comparing an output voltage of the second voltage regulator to a circuit leakage voltage for the second circuit under test; and determining that the second circuit under test does not include a short by detecting that a difference between the output voltage of the second voltage regulator and the circuit leakage voltage is less than a threshold.

In one or more embodiments, applying the voltage to the input voltage rail that provides power to a second circuit under test via a second voltage regulator is carried out by introducing the voltage to one or more pins of the integrated circuit. In one or more embodiments, disabling the second voltage regulator is carried out by adjusting the gate voltage provided to the transistor of the second voltage regulator such that no voltage is supplied at the drain of the transistor.

In one or more embodiments, after disabling the second voltage regulator, comparing an output voltage of the first voltage regulator to a circuit leakage voltage for the second circuit under test is carried out by measuring the output voltage at a connection to the drains of second voltage regulator. In one or more embodiments, determining that the second circuit under test does not include a short by detecting that a difference between the output voltage of the second voltage regulator and the circuit leakage voltage is less than a threshold is carried out by measuring the difference between the output voltage and the circuit leakage voltage from the comparison and determining the that difference is less than the threshold. Detecting that a difference between the output voltage and the circuit leakage voltage is less than the threshold indicates that the circuit under test does not have a short.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
providing an integrated circuit having a first voltage regulator in a voltage domain, a first circuit under test, a regulator disable logic unit, and a short detection logic unit;
applying a voltage to the first circuit under test via the first voltage regulator;
disabling the first voltage regulator by the regulator disable logic unit;
after disabling the first voltage regulator, comparing, by the short detection logic unit, an output voltage of the first voltage regulator to a circuit leakage voltage value expected for the first circuit under test; and
determining that a short exists by detecting that a difference between the output voltage of the first voltage regulator and the circuit leakage voltage value is greater than a threshold.

2. The method of claim 1, wherein determining that the short exists comprises determining that the short exists in the first voltage regulator, in the first circuit under test, or in the voltage domain.

3. The method of claim 1, wherein comparing the output voltage of the first voltage regulator to a circuit leakage voltage value expected for the first circuit under test comprises measuring the output voltage at a connection to a drain of first voltage regulator.

4. The method of claim 1, wherein comparing the output voltage of the first voltage regulator to a circuit leakage voltage value expected for the first circuit under test comprises measuring the output voltage of the first voltage regulator using a measurement logic unit.

5. The method of claim 1, wherein the threshold is an acceptable range of leakage voltage of the voltage regulator above the circuit leakage voltage value.

6. The method of claim 1, wherein the first voltage regulator is within the voltage domain.

7. The method of claim 1, wherein the voltage domain comprises a plurality of voltage regulators and the first voltage regulator is one of the plurality of voltage regulators, the plurality of voltage regulators being connected to an input voltage rail.

8. The method of claim 1, wherein the first voltage regulator comprises an amplifier and a transistor.

9. The method of claim 1, wherein the integrated circuit comprises a plurality of voltage domains and the voltage domain is one of the plurality of voltage domains.

10. The method of claim 1, wherein the output voltage is compared with the circuit leakage voltage value by the short detection logic unit, the short detection logic unit being external to the voltage domain.

11. A computer system comprising:
a processor set;
one or more computer-readable storage media; and
program instructions stored on the one or more computer-readable storage media to cause the processor set to perform operations comprising:
providing an integrated circuit having a first voltage regulator in a voltage domain, a first circuit under test, a regulator disable logic unit, and a short detection logic unit;
applying a voltage to the first circuit under test via the first voltage regulator;
disabling the first voltage regulator by the regulator disable logic unit;
after disabling the first voltage regulator, comparing, by the short detection logic unit, an output voltage of the first voltage regulator to a circuit leakage voltage value expected for the first circuit under test; and
determining that a short exists by detecting that a difference between the output voltage of the first voltage regulator and the circuit leakage voltage value is greater than a threshold.

12. The computer system of claim 11, wherein determining that the short exists comprises determining that the short exists in the first voltage regulator, in the first circuit under test, or in the voltage domain.

13. The computer system of claim 11, wherein comparing the output voltage of the first voltage regulator to a circuit leakage voltage value expected for the first circuit under test comprises measuring the output voltage at a connection to a drain of first voltage regulator.

14. The computer system of claim 11, wherein comparing the output voltage of the first voltage regulator to a circuit leakage voltage value expected for the first circuit under test comprises measuring the output voltage of the first voltage regulator using a measurement logic unit.

15. The computer system of claim 11, wherein the threshold is an acceptable range of leakage voltage of the voltage regulator above the circuit leakage voltage value.

16. The computer system of claim 11, wherein the first voltage regulator is within the voltage domain.

17. The computer system of claim 11, wherein the voltage domain comprises a plurality of voltage regulators and the first voltage regulator is one of the plurality of voltage regulators, the plurality of voltage regulators being connected to an input voltage rail.

18. The computer system of claim 11, wherein the first voltage regulator comprises an amplifier and a transistor.

19. The computer system of claim 11, wherein the integrated circuit comprises a plurality of voltage domains and the voltage domain is one of the plurality of voltage domains.

20. A computer program product comprising:
one or more computer-readable storage media; and
program instructions stored on the one or more storage media to perform operations comprising:
providing an integrated circuit having a first voltage regulator in a voltage domain, a first circuit under test, a regulator disable logic unit, and a short detection logic unit;
applying a voltage to the first circuit under test via the first voltage regulator;
disabling the first voltage regulator by the regulator disable logic unit;
after disabling the first voltage regulator, comparing, by the short detection logic unit, an output voltage of the first voltage regulator to a circuit leakage voltage value expected for the first circuit under test; and
determining that a short exists by detecting that a difference between the output voltage of the first voltage regulator and the circuit leakage voltage value is greater than a threshold.
